(19) United States
(12) Patent Application Publication
(10) Pub. No.: US 2010/0197124 A1
(43) Pub. Date: Aug. 5, 2010

(54) Methods of Forming Semiconductor Devices Using Plasma Dehydrogenation and Devices Formed Thereby

(75) Inventors: Yong-kuk Jeong, Gyeonggi-do (KR); Dong-hee Yu, Fishkill, NY (US); Jong-ho Yang, Seoul (KR); Seong-dong Kim, LaGrangeville, NY (US)

Correspondence Address: MYERS BIGEL SIBLEY & SAJOVEC, PO BOX 37428, RALEIGH, NC, 27627, US

(73) Assignees: Samsung Electronics Co., Ltd.; International Business Machines Corporation

(21) Appl. No.: 12/363,980

(22) Filed: Feb. 2, 2009

(51) Int. Cl. H01L 21/426; H01L 21/4763

(52) U.S. Cl. 438/514; 438/595; 257/E21.474; 257/E21.495

(57) ABSTRACT

A semiconductor integrated circuit device with enhanced reliability is provided. The semiconductor integrated circuit device includes a semiconductor substrate; a gate insulation film that is provided on the semiconductor substrate; a gate electrode that is provided on the gate insulation film; and a sidewall spacer that is provided on side walls of the gate insulation film and the gate electrode and includes, wherein the sidewall spacer has a first sidewall spacer in contact with the gate electrode and a second sidewall spacer formed on the side walls of the first sidewall spacer, and a ratio of an Si—OH area to an Si—O area in at least one of the first and second sidewall spacers is 0.05 or less, as measured by Fourier Transform InfraRed (FTIR).

### FIELD OF THE INVENTION

The present invention relates to semiconductor integrated circuit devices and methods of fabricating the same and, more particularly, to semiconductor integrated circuit devices and methods of fabricating the same.

### BACKGROUND OF THE INVENTION

In metal-oxide semiconductor field effect transistors (MOSFET), gate electrodes formed on a semiconductor substrate are insulated by a thin gate insulating film interposed therebetween, and source/drain regions are formed at opposite sides of the gate electrodes. Recently, along with the increasing demand for miniaturization and high integration of a semiconductor memory device, various methods have been researched to form semiconductor devices having excellent performance while addressing problems associated with formation of highly integrated semiconductor devices.

For example, as a semiconductor device is miniaturized, a transistor channel length is scaled down and an electric field between source and drains is increased to thereby generate hot carriers with increased mobility. These hot carriers reduce the reliability of the semiconductor integrated circuit device. To overcome this problem, attempts to reduce intensity of the electric field have been proposed such that impurity doping concentrations are locally reduced by forming low concentration impurity extension regions at both sides of a gate electrode.

Spacers are generally formed on the extension regions, and impurities doped into a semiconductor substrate (e.g., boron (B)), may be out-diffused through the extension regions and the spacers, resulting in a reduction in the impurity concentration of the extension regions that may increase parasitic spreading resistance. As a result, the semiconductor device may deteriorate.

### SUMMARY OF THE INVENTION

According to an embodiment of the present invention, there is provided a semiconductor integrated circuit device including a semiconductor substrate, a gate insulation film that is provided on the semiconductor substrate, a gate electrode that is provided on the gate insulation film, and a sidewall spacer that is provided on side walls of the gate insulation film and the gate electrode. The sidewall spacer includes a first sidewall spacer in contact with the gate electrode and a second sidewall spacer formed on the side walls of the first sidewall spacer. A ratio of an Si—OH area to an Si—O area in at least one of the first and second sidewall spacers is 0.05 or less, as measured by Fourier Transform InfraRed (FTIR).

According to another embodiment of the present invention, there is provided a method of fabricating a semiconductor integrated circuit device including forming a gate insulation film and a gate electrode on a semiconductor substrate, conformally forming a first sidewall spacer layer on the semiconductor substrate, performing a first ion implantation process using as ion implantation masks the gate insulation film, the gate electrode and the first sidewall spacer layer formed on the gate insulation film and sidewalls of the gate electrode, conformally forming a second sidewall spacer layer on the semiconductor substrate, and dehydrogenizing the first and second sidewall spacer layers by performing a plasma treatment process on the semiconductor substrate.

### BRIEF DESCRIPTION OF THE DRAWINGS

The above and other features and advantages of the present invention will become more apparent by describing in detail preferred embodiments thereof with reference to the attached drawings in which:

FIG. 1 is a cross-sectional view of a semiconductor integrated circuit device according to a first embodiment of the present invention;

FIG. 2 is a cross-sectional view of a semiconductor integrated circuit device according to a second embodiment of the present invention;

FIG. 3 is a cross-sectional view of a semiconductor integrated circuit device according to a third embodiment of the present invention;

FIGS. 4 through 9 are cross-sectional views of interim structures for explaining a first exemplary method of fabricating the semiconductor integrated circuit device shown in FIG. 1;

FIGS. 10 and 11 are cross-sectional views of interim structures for explaining a second exemplary method of fabricating the semiconductor integrated circuit device shown in FIG. 1;

FIGS. 12 through 15 are cross-sectional views of interim structures for explaining a first exemplary method of fabricating the semiconductor integrated circuit device shown in FIG. 2;

FIGS. 16 through 18 are cross-sectional views of interim structures for explaining a second exemplary method of fabricating the semiconductor integrated circuit device shown in FIG. 2;

FIGS. 19 and 20 are cross-sectional views of interim structures for explaining an exemplary method of fabricating the semiconductor integrated circuit device shown in FIG. 3; and

FIG. 21 is a graph showing results obtained by evaluating a change in the components of an oxide layer formed on a transistor before and after O₃ or N₂ plasma treatment, as measured using Fourier Transform InfraRed spectrometer (FTIR).

### DETAILED DESCRIPTION OF THE INVENTION

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. Like reference numerals refer to like elements throughout the specification.

It will be understood that although the terms used herein are used to describe exemplary embodiments of the present invention, the invention should not be limited by these terms. It will be further understood that the terms “comprises” and/or “comprising” when used in this specification, specify the presence of stated features, regions, integers, steps, operations, elements, and/or components, but do not preclude the presence or addition of one or more other features, regions, integers, steps, operations, elements, components, and/or groups thereof.

The present invention will be described with reference to perspective views, cross-sectional views, and/or plan views, in which preferred embodiments of the invention are shown. Thus, the profile of an exemplary view may be modified according to manufacturing techniques and/or allowances. That is, the embodiments of the invention are not intended to limit the scope of the present invention but cover all changes and modifications that can be caused due to a change in manufacturing process. Thus, regions shown in the drawings are illustrated in schematic form and the shapes of the regions are presented simply by way of illustration and not as a limitation. In the drawings, various components may be exaggerated or reduced for clarity, and like numbers refer to like elements throughout the specification.

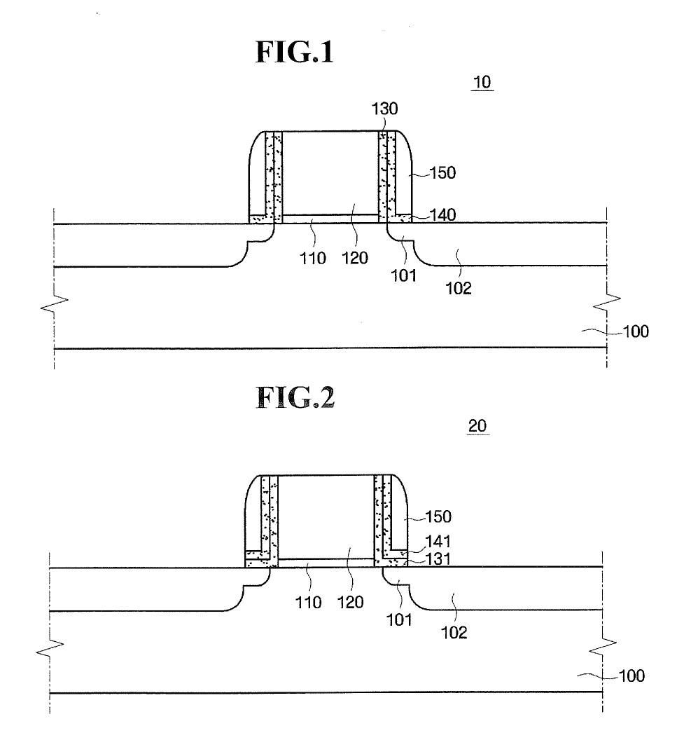

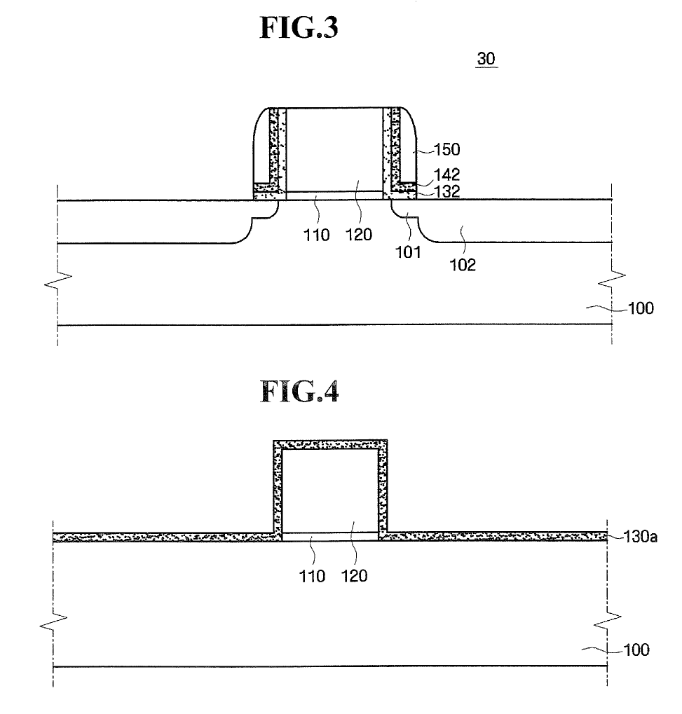

Hereinafter, semiconductor integrated circuit devices according to several embodiments of the present invention will be explained in more detail with reference to FIGS. 1 through 3. FIG. 1 is a cross-sectional view of a semiconductor integrated circuit device according to a first embodiment of the present invention, FIG. 2 is a cross-sectional view of a semiconductor integrated circuit device according to a second embodiment of the present invention, and FIG. 3 is a cross-sectional view of a semiconductor integrated circuit device according to a third embodiment of the present invention.

Each of the semiconductor integrated circuit devices 10, 20 and 30 according to several embodiments of the present invention includes a semiconductor substrate 100, a gate insulation film 110, a gate electrode 120, a extension region 101, a source/drain region 102, first sidewall spacers 130, 131, and 132, second sidewall spacers 140, 141, and 142, and a third sidewall spacer 150.

The semiconductor substrate 100 may be a silicon substrate, SOI (silicon on insulator) substrate, a Ga—As substrate, a Si—Ge substrate, a ceramic substrate, a quartz substrate, or a glass substrate for a display device. In addition, the semiconductor substrate 100 may be a P-type substrate or an N-type substrate. Although not shown, the semiconductor substrate 100 may further include a P-type epitaxial layer grown on the semiconductor substrate 100. Although not shown, the semiconductor substrate 100 may also include a P-type well or an N-type well doped with p-type or n-type impurities.

The gate insulation film 110 and the gate electrode 120 are formed on the semiconductor substrate 100. The gate insulation film 110 may be a layer made of silicon oxide (SiOx), silicon oxynitride (SiON), titanium oxide (TiOx), tantalum oxide (TaOx), or the like. The gate insulation film 110 may be deposited by chemical vapor deposition (CVD) or sputtering. The gate electrode 120 is formed on the gate insulation film 110, and may be a single layer of a polysilicon layer doped with N-type or P-type impurity, a metallic layer, a metal silicide layer, or a metal nitride layer, or a stacked layer thereof.

The first sidewall spacers 130, 131, and 132 and the second sidewall spacers 140, 141, and 142 are disposed on both sidewalls of the gate electrode 120 and the gate insulation film 110. The first sidewall spacers 130, 131, and 132 and the second sidewall spacers 140, 141, and 142 may be an oxide layer. More specifically, the first sidewall spacers 130, 131, and 132 and the second sidewall spacers 140, 141, and 142 may be a low temperature oxide (LTO).

A ratio of an Si—OH area to an Si—O area in at least one of the first sidewall spacer 130, 131, 132 and the second sidewall spacer 140, 141, 142 may be 0.05 or less in, as measured by Fourier Transform InfraRed (FTIR). This is based on a new finding made by the present inventors, which has never been proposed hitherto, that the higher the hydrogen content of a sidewall spacer, the higher probable impurities contained in the semiconductor substrate 100 are diffused outwardly.

In more detail, as shown in FIGS. 1 and 2, a ratio of an Si—OH area to an Si—O area in both the first sidewall spacer 130, 131 and the second sidewall spacer 140, 141 may be 0.05 or less, as measured by FTIR. Alternatively, as shown in FIG. 3, a ratio of an Si—OH area to an Si—O area only in the first sidewall spacer 132 may be 0.05 or less, as measured by FTIR. As described above, the ratio of an Si—OH area to an Si—O area in at least one of the first sidewall spacer and the second sidewall spacer has only to be 0.05 or less. Although not shown in the drawing, according to alternative embodiment, only the second sidewall spacer may have an area ratio of 0.05 or less, and the invention is not limited to the illustrated embodiments.

Referring back to FIG. 1, the first sidewall spacer 130 may be formed on both sidewalls of the gate electrode 120 and the gate insulation film 110. The second sidewall spacer 140 may be conformally formed in an L-shape in contact with both sidewalls of the gate electrode 120 and on a portion of a top surface of the semiconductor substrate 100.

As described above, a ratio of an Si—OH area to an Si—O area in the first sidewall spacer 130 and the second sidewall spacer 140 may be 0.05 or less, as measured by FTIR.

Referring to FIG. 2, the first sidewall spacer 131 may be conformally formed on both sidewalls of the gate electrode 120 and the gate insulation film 110 and on a portion of a top surface of the semiconductor substrate 100. That is to say, the first sidewall spacer 131 may be formed in an L-shape in contact with the gate electrode 120, the gate insulation film 110 and on a portion of the top surface of the semiconductor substrate 100.

The second sidewall spacer 141 is conformally formed on the first sidewall spacer 131 in an L-shape similar to a case of the first sidewall spacer 131. That is to say, the second sidewall spacer 141 may be conformally formed on the gate electrode 120, the gate insulation film 110 and a portion of the top surface of the semiconductor substrate 100. As described above, a ratio of an Si—OH area to an Si—O area in both the first sidewall spacer 131 and the second sidewall spacer 141 maybe 0.05 or less, as measured by FTIR.

Referring to FIG. 3, the first sidewall spacer 132 and the second sidewall spacer 142 may have substantially the same shapes as in the embodiment illustrated in FIG. 2. The current embodiment is substantially the same as the embodiment illustrated in FIG. 2, except that a ratio of an Si—OH area to an Si—O area only in the first sidewall spacer 132 is 0.05 or less, as measured by FTIR.

In the semiconductor integrated circuit devices 10, 20 and 30 according to some embodiments of the present invention, a third sidewall spacer 150 may be formed on each of the second sidewall spacers 140, 141 and 142, respectively. The third sidewall spacer 150 may be, for example, a nitride layer.

In addition, the extension region 101 and the source/drain region 102 may be formed in the semiconductor substrate 100. The extension region 101 may have low-concentration impurities. The extension region 101 may be formed on outer walls of the first sidewall spacer 130, 131, 132. Specifically, the extension region 101 may be aligned with sidewalls in contact with the second sidewall spacer 140, 141, 142.

The source/drain region 102 may contain impurities in a higher concentration than the extension region 101. The source/drain region 102 may be aligned with outer sidewalls of the third sidewall spacer 150. In the case of forming an NMOS transistor, n-type impurities, e.g., phosphorus (P), asbestos (As), or the like, may be contained in the source/drain region 102. On the other hand, in the case of forming a PMOS transistor, p-type impurities, e.g., boron (B) or the like, may be contained in the source/drain region 102.

The semiconductor integrated circuit devices 10, 20 and 30 according to some embodiments of the present invention includes a ratio of an Si—OH area to an Si—O area in at least one sidewall spacer being 0.05 or less, as measured by FTIR, thereby preventing impurities contained in the semiconductor substrate 100, e.g., boron (B) or the like, from being diffused outwardly. Accordingly, improvement in the reliability of the semiconductor integrated circuit device according to the present invention can be ensured.

Hereinafter, a method of fabricating the semiconductor integrated circuit device according to the first embodiment of the present invention will be described with reference to FIGS. 4 through 9. FIGS. 4 through 9 are cross-sectional views of interim structures for explaining a method of fabricating the semiconductor integrated circuit device shown in FIG. 1.

Referring to FIG. 4, the gate insulation film 110, the gate electrode 120, and a first sidewall spacer layer 130a are formed on the semiconductor substrate 100.

Although not shown in the drawing, the gate insulation film 110 and the gate electrode 120 may be formed by stacking layers for forming the gate insulation film 110 and the gate electrode 120 on the semiconductor substrate 100 using a deposition technique, e.g., chemical vapor deposition (CVD), and then patterning the stacked structure.

Next, the first sidewall spacer layer 130a is formed on the semiconductor substrate 100 having the gate insulation film 110 and the gate electrode 120 by CVD or low temperature chemical vapor deposition (LTCVD). The first sidewall spacer layer 130a may be, for example, an oxide layer, more specifically, a low temperature oxide (LTO) layer.

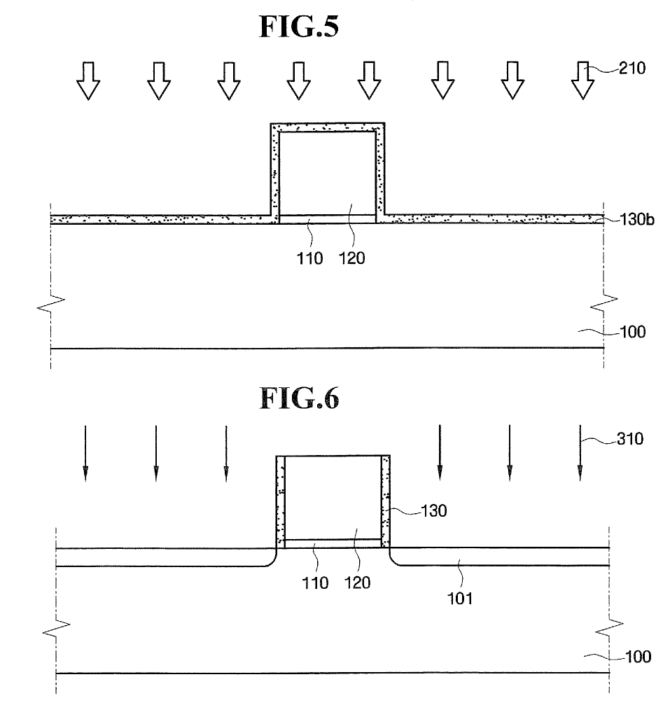

Referring to FIG. 5, first plasma treatment 210 is performed on the semiconductor substrate 100 to then form a dehydrogenized first sidewall spacer layer 130b.

The first plasma treatment process 210 may be performed using a gas capable of dehydrogenizing the second sidewall spacer layer (130a of FIG. 5) formed after deposition, for example, a gas containing nitrogen (N) or oxygen (O), as a reactant gas. In more detail, the reactant gas may be selected from N₂, O₂, O₃, N₂O, and combinations thereof.

The first plasma treatment 210 is carried out to dehydrogenize the first sidewall spacer layer 130a. As a result, a ratio of an Si—OH area to an Si—O area in the dehydrogenized first sidewall spacer layer 130b formed after performing the first plasma treatment 210 may be 0.05 or less, as measured by FTIR. Various processing conditions of the first plasma treatment 210, including the kind of reactant gas used, processing time, processing pressure, or other processing conditions, may be appropriately controlled such that the ratio of an Si—OH area to an Si—O area in the dehydrogenized first sidewall spacer layer 130b is 0.05 or less.

Referring to FIG. 6, the first sidewall spacer 130 is formed and a first ion implantation 310 is then carried out using the first sidewall spacer 130 as an ion implantation.

In detail, the first sidewall spacer 130 may be formed by anisotropically etching or etching back the first sidewall spacer layer (130b of FIG. 5).

Subsequently, the first ion implantation 310 may be carried out by implanting low-concentration impurities using the first sidewall spacer 130 as an ion implantation. The first ion implantation 310 allows the extension region 101 aligned with the outer sidewalls of the first sidewall spacer 130 to be formed on the semiconductor substrate 100. As described above, in the case of forming an NMOS transistor, the low-concentration impurities may be n-type impurities, e.g., phosphorus (P), arsenic (As), or the like. On the other hand, in the case of forming a PMOS transistor, the low-concentration impurities may be p-type impurities, e.g., boron (B) or the like.

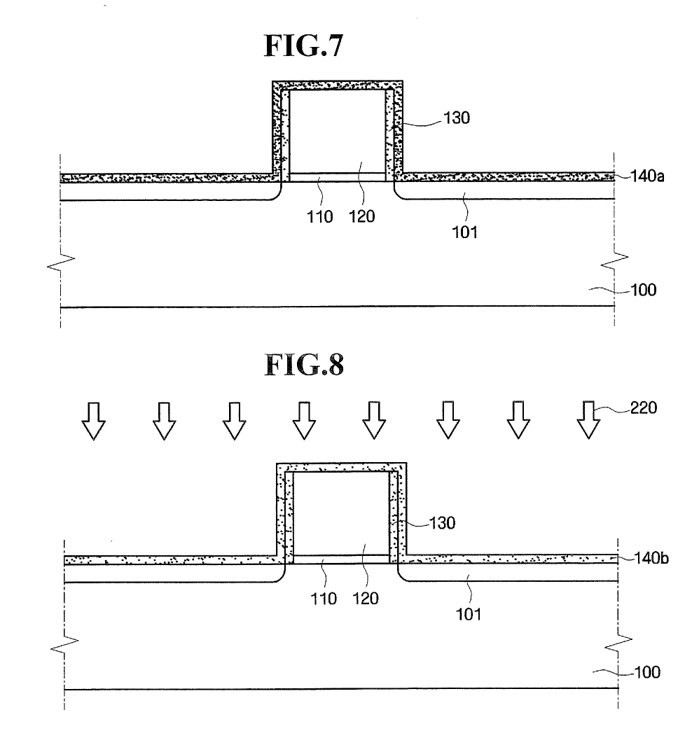

Referring to FIG. 7, a second sidewall spacer layer 140a is formed on the semiconductor substrate 100. The second sidewall spacer layer 140a may be conformally formed on top of the semiconductor substrate 100 using a deposition technique, e.g., CVD or LTCVD. The second sidewall spacer layer 140a may be, for example, an oxide layer or a low temperature oxide (LTO) layer.

Referring to FIG. 8, a second plasma treatment process 220 is carried out to form a dehydrogenized second sidewall spacer layer 140a.

The second plasma treatment process 220 may be performed using a gas capable of dehydrogenizing the second sidewall spacer layer (140a of FIG. 7) formed immediately after deposition, for example, a gas containing nitrogen (N) or oxygen (O), as a reactant gas. In more detail, the reactant gas may be selected from N₂, O₂, O₃, N₂O, and combinations thereof. A ratio of an Si—OH area to an Si—O area in the dehydrogenized second sidewall spacer layer 140b formed after performing the second plasma treatment process 220 may be 0.05 or less, as measured by FTIR. Various processing conditions of the second plasma treatment process 220, including the kind of reactant gas used, processing time, processing pressure, or other processing conditions, may be appropriately controlled such that a ratio of an Si—OH area to an Si—O area in the dehydrogenized second sidewall spacer layer 140b is 0.05 or less.

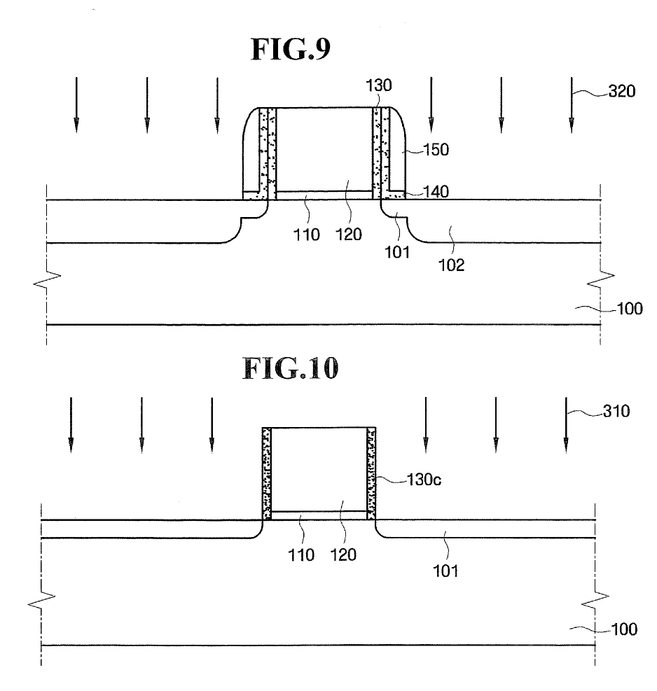

Referring to FIG. 9, the second and third sidewall spacers 140 and 150 are formed on the semiconductor substrate 100 and second ion implantation 320 is then carried out, which will now be described in detail.

The forming of the third sidewall spacer 150 may include forming a third sidewall spacer layer (not shown) using a technique, e.g., CVD or sputtering. Here, the third sidewall spacer layer may be, for example, a nitride layer. The second and third sidewall spacers 140 and 150 formed on both sidewalls of the gate electrode may be formed by anisotropically etching or etching back the third sidewall spacer layer and the second sidewall spacer layer (140b of FIG. 8) formed on top of the semiconductor substrate 100. The source/drain region 102 may contain impurities in a higher concentration than the extension region 101

Subsequently, the second ion implantation 320 may be performed by implanting high-concentration impurities using the gate insulation film 110, the gate electrode 120, and the first, second and third sidewall spacers 130, 140, 150 as ion implantation masks. Here, the high-concentration impurities may have a concentration higher than that in the first ion implantation process (310 of FIG. 6). The second ion implantation 320 allows the source/drain region 102 aligned with outer sidewalls of the third sidewall spacer 150.

In the first exemplary fabrication method of the semiconductor integrated circuit device according to the first embodiment of the present invention, the first and second plasma treatment processes are performed on the semiconductor substrate to thus form dehydrogenized, first and second sidewall spacers, thereby preventing impurities contained in the semiconductor substrate 100 from being diffused outwardly. Accordingly, the semiconductor integrated circuit device having enhanced reliability can be fabricated.

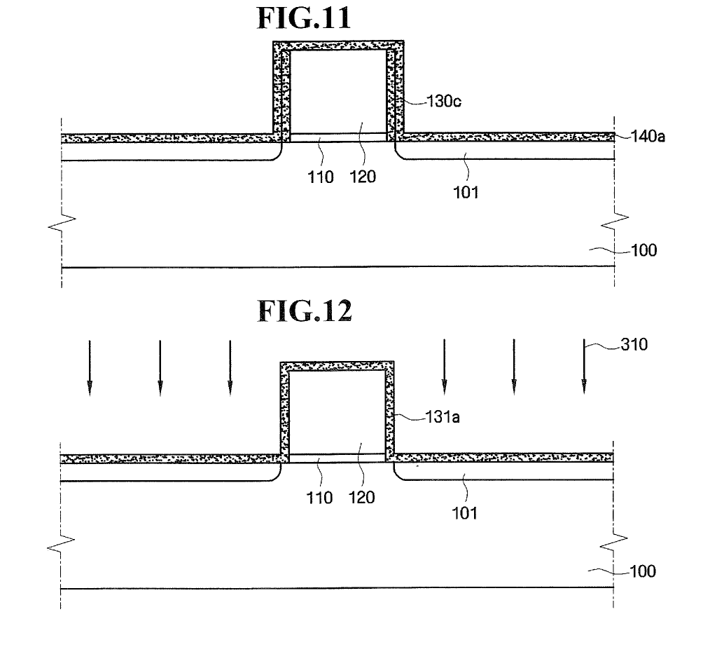

Hereinafter, a second exemplary fabrication method of the semiconductor integrated circuit device according to the first embodiment of the present invention will be described with reference to FIGS. 10 and 11. FIGS. 10 and 11 are cross-sectional views of interim structures for explaining another exemplary method of fabricating the semiconductor integrated circuit device shown in FIG. 1.

The second exemplary fabrication method is different from the first exemplary fabrication method in that prior to the first plasma treatment process, the forming of the first sidewall spacer and the performing of the first ion implantation process are carried out. That is to say, the second exemplary fabrication method is the same as the first second exemplary fabrication method of the semiconductor integrated circuit device according to the first embodiment of the present invention in terms of operations preceding the operation illustrated in FIG. 4, that is, the operation of forming the first sidewall spacer layer 130a. Thus, in the following description, only operations subsequent to the operation of forming the first sidewall spacer layer 130a will be described. In addition, substantially the same functional components as those of the first exemplary fabrication method of the semiconductor integrated circuit device according to the first embodiment of the present invention are identified by the same reference numerals, and their repetitive description will be omitted.

Referring to FIG. 10, a first sidewall spacer 130c is formed on the semiconductor substrate 100 and first ion implantation 310 is then carried out.

In detail, the first sidewall spacer 130c is formed by anisotropically etching or etching back the first sidewall spacer layer (130a of FIG. 4) conformally formed on the semiconductor substrate 100 having the gate insulation film 110 and the gate electrode 120. Subsequently, the first ion implantation 310 may be carried out by implanting low-concentration impurities using the gate insulation film 110, the gate electrode 120, and the first sidewall spacer 130c as ion implantations.

Referring to FIG. 1, a second sidewall spacer layer 140a is formed on the semiconductor substrate 100.

The second sidewall spacer layer 140a may be conformally formed on the semiconductor substrate 100 having the first sidewall spacer 130c. Therefore, the first sidewall spacer 130c and the second sidewall spacer layer 140a are both in a state in which they are not dehydrogenized.

Next, a plasma treatment process is performed on the first sidewall spacer 130c and the second sidewall spacer layer 140a. While in the first exemplary fabrication method, the first sidewall spacer layer and the second sidewall spacer layer are independently subjected to plasma treatment, respectively (see 210 of FIG. 5 and 220 of FIG. 8), in the second exemplary fabrication method, the first sidewall spacer and the second spacer layer are dehydrogenized by performing plasma treatment (not shown) just one time.

The following operations, including forming second and third sidewall spacers and performing a second ion implantation process using the first and second sidewall spacers as ion implantation masks, are substantially same as those in the first exemplary fabrication method illustrated in FIGS. 1 through 9.

In the second exemplary fabrication method of the semiconductor integrated circuit device according to the first embodiment of the present invention, since the dehydrogenized, first and second sidewall spacers are formed by performing plasma treatment (not shown) just one time, the semiconductor integrated circuit device having enhanced reliability can be fabricated, thereby simplifying the fabrication process and enhancing the processing efficiency.

Hereinafter, a first exemplary method of fabricating the semiconductor integrated circuit device according to the second embodiment of the present invention, as shown in FIG. 2, will be described with reference to FIGS. 12 through 15. FIGS. 12 through 15 are cross-sectional views of interim structures for explaining a first exemplary method of fabricating the semiconductor integrated circuit device shown in FIG. 2.

The first exemplary fabrication method of the semiconductor integrated circuit device according to the second embodiment of the present invention is different from some exemplary fabrication methods of the semiconductor integrated circuit device according to the first embodiment of the present invention in that the first plasma treatment process is performed on the first sidewall spacer layer. That is to say, the first exemplary fabrication method of the semiconductor integrated circuit device according to the second embodiment of the present invention is the same as the first exemplary fabrication methods of the semiconductor integrated circuit device according to the first embodiment of the present invention in terms of operations preceding the operation illustrated in FIG. 4, that is, the operation of forming the first sidewall spacer layer 130a. Thus, in the following description, only operations subsequent to the operation of forming the first sidewall spacer layer 130a will be described.

Referring to FIG. 12, first ion implantation 310 is carried out on the semiconductor substrate 100 having a first sidewall spacer 130a.

In detail, the first ion implantation 310 may be carried out using as ion implantation masks a gate insulation film 110 and a gate electrode 120 and the first sidewall spacer 130a formed at sidewalls of the gate insulation film 110 and the gate electrode 120. The first ion implantation 310 may be carried out by implanting low-concentration impurities. The first ion implantation 310 allows a extension region 101 to be aligned with outer sidewalls of the first sidewall spacer layer 131a formed at sidewalls of the gate insulation film 110 and the gate electrode 120. The first ion implantation 310 may be performed under appropriate processing conditions controlled such that impurities are doped into the semiconductor substrate 100 through the first sidewall spacer layer 131a formed on a top surface of the semiconductor substrate 100.

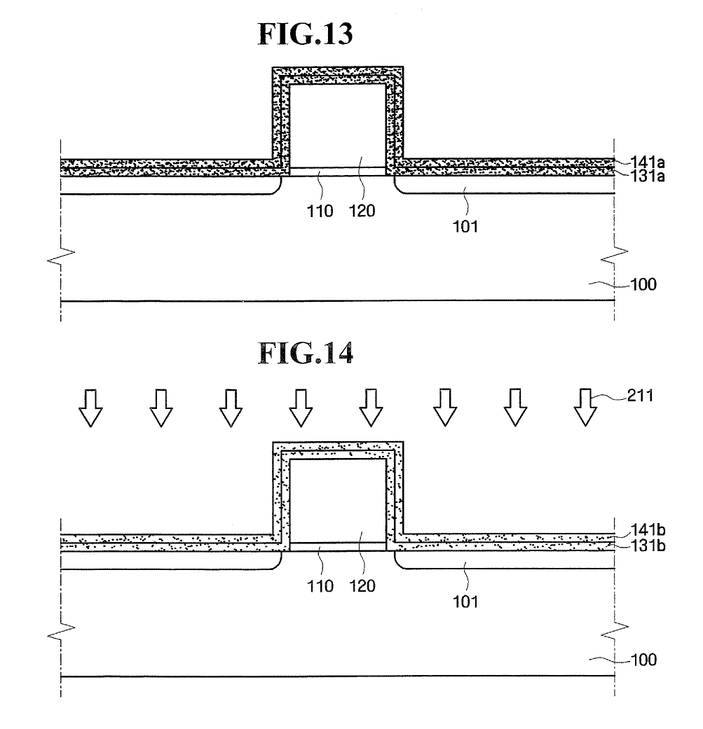

Referring to FIG. 13, a second sidewall spacer layer 141a may be conformally formed on top of the semiconductor substrate 100.

In detail, the second sidewall spacer layer 141a may be conformally formed on the first sidewall spacer layer 131a using a deposition technique, e.g., CVD or LTCVD. Here, the second sidewall spacer layer 141a may be, for example, an oxide layer, more specifically a low temperature oxide (LTO) layer.

Referring to FIG. 14, plasma treatment process 211 is performed on the semiconductor substrate 100.

Here, the plasma treatment 211 allows the first and second sidewall spacer layers (see 131a and 141a of FIG. 13) formed immediately after deposition to be dehydrogenized. That is to say, during the plasma treatment 211 in the first exemplary fabrication method of the semiconductor integrated circuit device according to the second embodiment of the present invention, both the first sidewall spacer layer 131a and the second sidewall spacer layer 141a are dehydrogenized. Thus, the plasma treatment 211 may be performed under different processing conditions from the plasma treatment processes (see 210 of FIG. 5 and 220 of FIG. 8). For example, the plasma treatment 211 may requires a relatively long processing time.

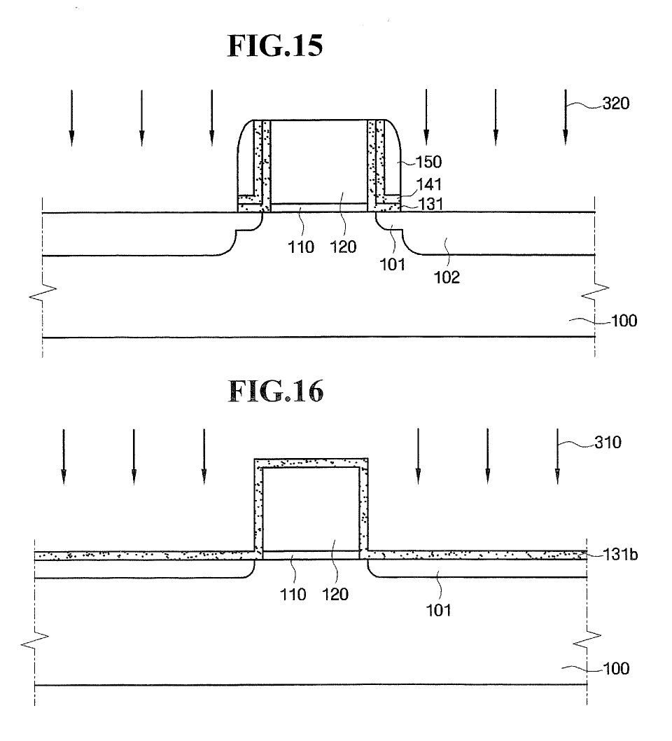

Referring to FIG. 15, first, second and third sidewall spacers 131, 141 and 150 are formed and second ion implantation 320 is then carried out, which will now be described in detail.

The forming of the first, second and third sidewall spacers 131, 141 and 150 may include forming a third sidewall spacer layer (not shown) on top of the dehydrogenized, first and second sidewall spacer layers (see 131b and 140b of FIG. 8) using a technique, e.g., CVD or the like. Here, the third sidewall spacer layer may be, for example, a nitride layer.

Next, the first, second and third sidewall spacers 131, 141 and 150 may be formed by anisotropically etching or etching back the first, second and third sidewall spacer layers formed on top of the semiconductor substrate 100.

Then, the second ion implantation 320 may be carried out by implanting high-concentration impurities using the first, second and third sidewall spacers 131, 141 and 150 as ion implantation masks. The second ion implantation 320 allows the source/drain region 102 aligned with outer sidewalls of the third sidewall spacer 150.

In the second exemplary fabrication method of the semiconductor integrated circuit device according to the second embodiment of the present invention, it is possible to prevent impurities of the semiconductor substrate from being diffused outwardly by forming the dehydrogenized, first and second sidewall spacers, thereby fabricating the semiconductor integrated circuit device having enhanced reliability. In addition, the first and second sidewall spacers can be dehydrogenized by performing plasma treatment (not shown) just one time, thereby enhancing the processing efficiency.

Hereinafter, a second exemplary method of fabricating the semiconductor integrated circuit device according to the second embodiment of the present invention, as shown in FIG. 2, will be described with reference to FIGS. 16 through 18. FIGS. 16 through 18 are cross-sectional views of interim structures for explaining a second exemplary method of fabricating the semiconductor integrated circuit device shown in FIG. 2.

The second exemplary fabrication method of the semiconductor integrated circuit device according to the second embodiment of the present invention is different from the first exemplary fabrication method of the semiconductor integrated circuit device according to the second embodiment of the present invention in that plasma treatment is performed independently on the first and second sidewall spacer layers, respectively. That is to say, the second exemplary fabrication method is the same as the first second exemplary fabrication method of the semiconductor integrated circuit device according to the first embodiment of the present invention in terms of operations preceding the operation illustrated in FIG. 5, that is, the operation of performing the first plasma treatment process on the first sidewall spacer layer (130a of FIG. 5). Thus, in the following description, only operations subsequent to the operation of performing the first sidewall spacer layer 130a will be described.

Referring to FIG. 16, first ion implantation 310 is carried out on the semiconductor substrate 100 having a first sidewall spacer 131a.

In detail, the first ion implantation 310 may be carried out using as ion implantation masks a gate insulation film 110 and a gate electrode 120 and the first sidewall spacer 131a formed at sidewalls of the gate insulation film 110 and the gate electrode 120. The first ion implantation 310 may be carried out by implanting low-concentration impurities. The first ion implantation 310 allows a extension region 101 to be aligned with outer sidewalls of the first sidewall spacer layer 131b formed at sidewalls of the gate insulation film 110 and the gate electrode 120. Here, the first ion implantation 310 may be performed under the processing condition controlled such that impurities are doped into the top surface of the semiconductor substrate 100 through the first sidewall spacer layer 131b formed on the top surface of the semiconductor substrate 100.

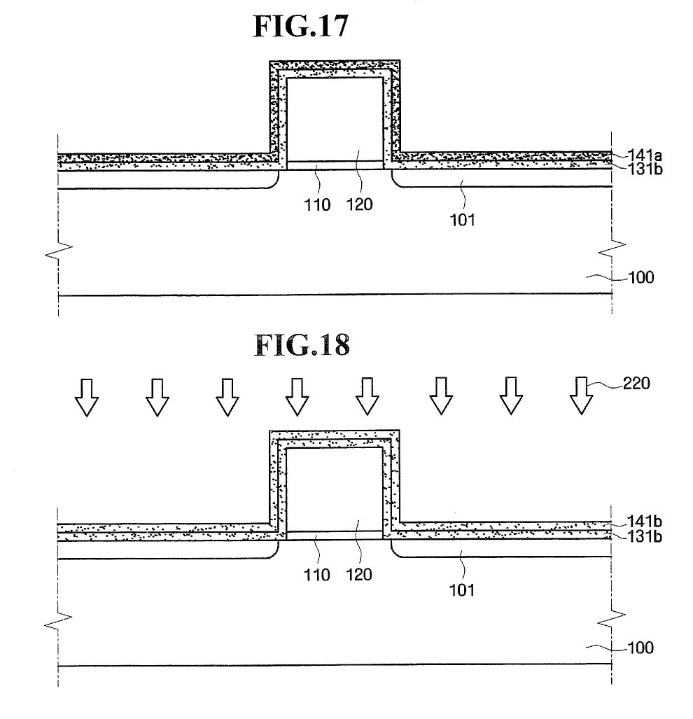

Referring to FIG. 17, a second sidewall spacer layer 141a may be conformally formed on the first sidewall spacer layer 131b.

In detail, the second sidewall spacer layer 141a may be conformally formed on the semiconductor substrate 100 having the first sidewall spacer layer 131b. Here, the second sidewall spacer layer 141a may be, for example, an oxide layer, more specifically a low temperature oxide (LTO) layer.

Referring to FIG. 18, a second plasma treatment process 220 is performed on the semiconductor substrate 100 to thus form a second sidewall spacer layer 141b.

The plasma treatment process 220 allows the second sidewall spacer layer (see 141a of FIG. 17) formed immediately after deposition to be dehydrogenized. Here, the first sidewall spacer layer 131b is in a dehydrogenized state. Accordingly, the second plasma treatment process 220 in the this exemplary fabrication method of the semiconductor integrated circuit device according to the second embodiment of the present invention is performed under different processing conditions from the plasma treatment 211 during which both the first and second sidewall spacer layers are dehydrogenized.

Thereafter, operations of forming a third sidewall spacer layer and forming the first, second and third sidewall spacers are substantially the same as those of the first exemplary fabrication method of the semiconductor integrated circuit device according to the second embodiment of the present invention, and their repetitive description will be omitted.

In the second exemplary fabrication method of the semiconductor integrated circuit device according to the second embodiment of the present invention, out-diffusion of impurities contained in the semiconductor substrate can be avoided by the first and second sidewall spacer layers dehydrogenized by performing plasma treatment. Accordingly, the semiconductor integrated circuit device having enhanced reliability can be fabricated.

Referring to FIG. 16, first ion implantation 310 is carried out on the semiconductor substrate 100 having a first sidewall spacer 131a.

In detail, the first ion implantation 310 may be carried out using as ion implantation masks a gate insulation film 110 and a gate electrode 120 and the first sidewall spacer 131a formed at sidewalls of the gate insulation film 110 and the gate electrode 120. The first ion implantation 310 may be carried out by implanting low-concentration impurities. The first ion implantation 310 allows a extension region 101 to be aligned with outer sidewalls of the first sidewall spacer layer 131b formed at sidewalls of the gate insulation film 110 and the gate electrode 120. Here, the first ion implantation 310 may be performed under the processing condition controlled such that impurities are doped into the top surface of the semiconductor substrate 100 through the first sidewall spacer layer 131b formed on the top surface of the semiconductor substrate 100.

Referring to FIG. 17, a second sidewall spacer layer 141a may be conformally formed on the first sidewall spacer layer 131b.

In detail, the second sidewall spacer layer 141a may be conformally formed on the semiconductor substrate 100 having the first sidewall spacer layer 131b. Here, the second sidewall spacer layer 141a may be, for example, an oxide layer, more specifically a low temperature oxide (LTO) layer.

Referring to FIG. 18, a second plasma treatment process 220 is performed on the semiconductor substrate 100 to thus form a second sidewall spacer layer 141b.

The plasma treatment process 220 allows the second sidewall spacer layer (see 141a of FIG. 17) formed immediately after deposition to be dehydrogenized. Here, the first sidewall spacer layer 131b is in a dehydrogenized state. Accordingly, the second plasma treatment process 220 in the this exemplary fabrication method of the semiconductor integrated circuit device according to the second embodiment of the present invention is performed under different processing conditions from the plasma treatment 211 during which both the first and second sidewall spacer layers are dehydrogenized.

Thereafter, operations of forming a third sidewall spacer layer and forming the first, second and third sidewall spacers are substantially the same as those of the first exemplary fabrication method of the semiconductor integrated circuit device according to the second embodiment of the present invention, and their repetitive description will be omitted.

In the second exemplary fabrication method of the semiconductor integrated circuit device according to the second embodiment of the present invention, out-diffusion of impurities contained in the semiconductor substrate can be avoided by the first and second sidewall spacer layers dehydrogenized by performing plasma treatment. Accordingly, the semiconductor integrated circuit device having enhanced reliability can be fabricated.

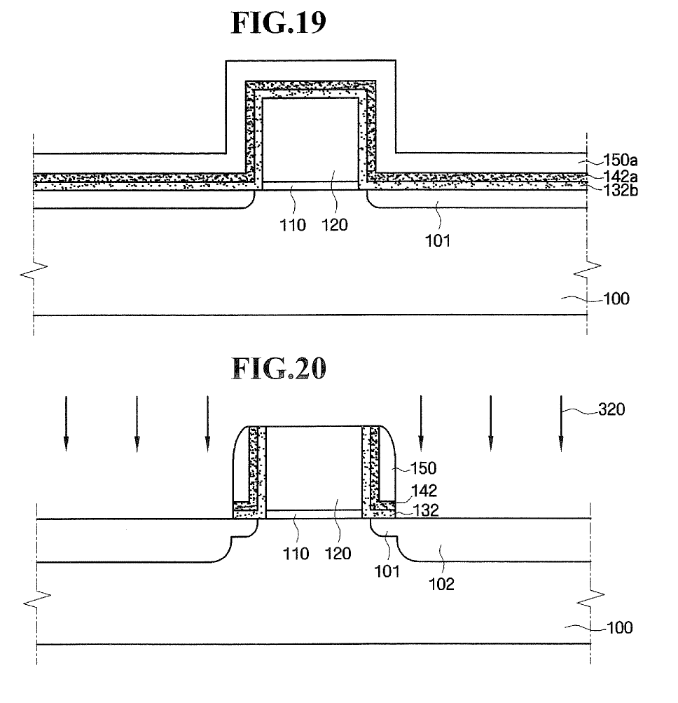

Hereinafter, an exemplary method of fabricating the semiconductor integrated circuit device according to the third embodiment of the present invention with reference to FIGS. 19 and 20. FIGS. 19 and 20 are cross-sectional views of interim structures for explaining an exemplary method of fabricating the semiconductor integrated circuit device shown in FIG. 3.

This exemplary method of fabricating the semiconductor integrated circuit device according to the third second embodiment of the present invention is different from the second exemplary method of fabricating the semiconductor integrated circuit device according to the second embodiment of the present invention in that a plasma treatment process is carried out on only a first sidewall spacer layer. That is to say, this exemplary fabrication method of the semiconductor integrated circuit device according to the third embodiment of the present invention is the same as the second exemplary fabrication methods of the semiconductor integrated circuit device according to the second embodiment of the present invention in terms of operations preceding the operation of forming the second sidewall spacer layer, as shown in FIG. 17. Thus, in the following description, only operations subsequent to the operation shown in FIG. 17 will be described.

Referring to FIG. 19, a third sidewall spacer layer 150a is formed on a semiconductor substrate 100.

In detail, the third sidewall spacer layer 150a may be formed on the semiconductor substrate 100 having a dehydrogenized first sidewall spacer layer 132b and a second sidewall spacer layer 142a formed immediately after deposition, using a deposition technique, e.g., CVD. Here, the third sidewall spacer layer 150a may be, for example, a nitride layer.

Referring to FIG. 20, first, second and third sidewall spacers 132, 142 and 150 are formed and second ion implantation 320 is then carried out, which will now be described in detail.

Next, the first, second and third sidewall spacers 132, 142 and 150 may be formed by anisotropically etching or etching back the first, second and third sidewall spacer layers (see 132b, 142a and 150a of FIG. 19).

Subsequently, the second ion implantation 320 may be carried out by implanting high-concentration impurities using the first, second and third sidewall spacers 132, 142 and 150 as ion implantation masks. The second ion implantation 320 allows a source/drain region 202 aligned with outer sidewalls of the third sidewall spacer 150.

In the exemplary fabrication method of the semiconductor integrated circuit device according to the third embodiment of the present invention, it is possible to prevent impurities of the semiconductor substrate from being diffused outwardly by forming the dehydrogenized, first sidewall spacer, thereby fabricating the semiconductor integrated circuit device having enhanced reliability. In addition, plasma treatment is performed only on the first sidewall spacer layer, that is, the plasma treatment is performed just one time, thereby simplifying the fabrication process.

### EXPERIMENTAL EXAMPLE

A transistor was formed on a semiconductor substrate, an oxide layer was formed on the transistor, and components of the resultant structure were analyzed by FTIR.

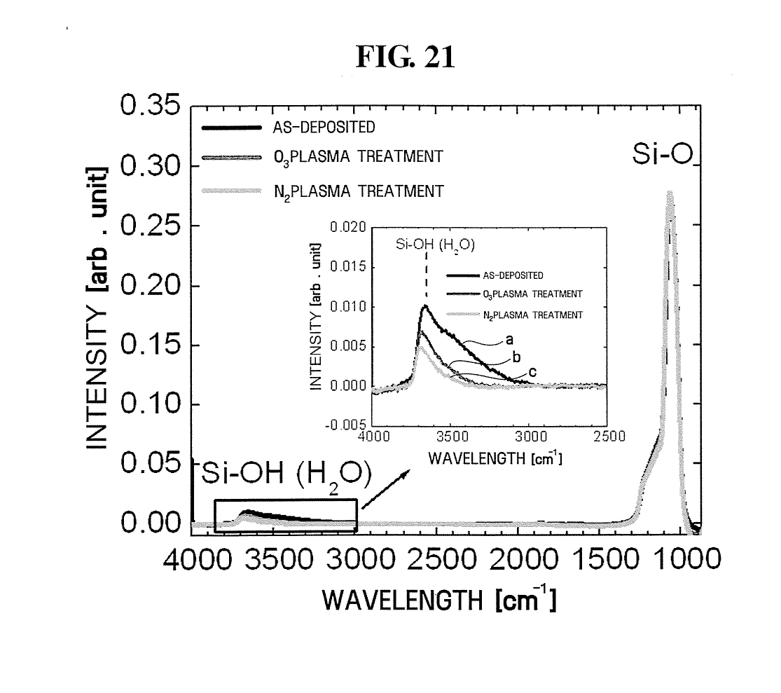

Subsequently, O₃ plasma treatment was performed on the semiconductor substrate, and components of the oxide layer were analyzed by FTIR. N₂ plasma treatment was also performed using the same processing steps. The results are shown in FIG. 21.

Referring to FIG. 21, the x-axis represents wavelength (cm⁻¹) and the y-axis represents absorbance. According to FTIR analysis, infrared radiation is applied to a target molecule to absorb wavelength in a range of about 4000 to about 400 cm⁻¹, where the wavelength has unique oscillation energy depending on the bonding structure of atoms in the target molecule, to then emit the wavelength. The components of the oxide layer were analyzed by measuring a change in the absorbance with respect to wavelength.

In FIG. 21, reference symbol ‘a’ represents the FTIR analysis result before plasma treatment, reference symbol ‘b’ represents the FTIR analysis result after O₃ plasma treatment, and reference symbol ‘c’ represents the FTIR analysis result after N₂ plasma treatment, respectively.

As can be observed by comparing ‘a’ and ‘b’ illustrated in FIG. 21, when O₃ plasma treatment was performed, as plotted as FTIR trace ‘b’, Si—OH (H₂O) peaks were substantially reduced, compared to a case when no plasma treatment was performed, as plotted as FTIR trace ‘a’. Comparison of the traces ‘a’ and ‘c’ demonstrated similar results. That is to say, when N₂ plasma treatment was performed, as plotted as FTIR trace ‘c’, Si—OH (H₂O) peaks were substantially reduced, compared to a case when no plasma treatment was performed, as plotted as FTIR trace ‘a’. This indicates that performing O₃ or N₂ plasma treatment allows the oxide layer to be dehydrogenized.

In the FTIR analysis results shown in FIG. 21, Si—O area, Si—OH area, and ratio of Si—OH area to Si—O area are summarized in the following Table.

| | Area by FTIR | | Area ratio by FTIR |
|---|---|---|---|
| | [Si—OH] | [Si—O] | [Si—OH]/[Si—O] |
| Before plasma treatment | 3.227 | 30.652 | 0.105 |
| After O₃ plasma treatment | 1.273 | 30.907 | 0.041 |
| After N₂ plasma treatment | 0.789 | 30.463 | 0.026 |

With regard to the Si—OH area, Si—OH areas with O₃ and N₂ plasma treatments were reduced to 1.273 and 0.789 and exhibited a reduction of 50% or higher, compared to the Si—OH area without O₃ or N₂ plasma treatment, that is, 3.227.

In addition, with regard to a ratio of the Si—OH area to the Si—O area, the ratios with O₃ and N₂ plasma treatments were 0.041 and 0.026, while the ratio without O₃ or N₂ plasma treatment was 0.105. This indicates that performing the O₃ or N₂ plasma treatment allows the oxide layer to be dehydrogenized.

While the present invention has been particularly shown and described with reference to exemplary embodiments thereof, it will be understood by those of ordinary skill in the art that various changes in form and details may be made therein without departing from the spirit and scope of the present invention as defined by the following claims. It is therefore desired that the present embodiments be considered in all respects as illustrative and not restrictive, reference being made to the appended claims rather than the foregoing description to indicate the scope of the invention.

1. A method of fabricating a field effect transistor, comprising:
forming a gate electrode on a semiconductor substrate;
forming an oxide spacer having hydrogen therein, on a sidewall of the gate electrode; and
removing hydrogen from the oxide spacer by exposing the oxide spacer to a plasma that converts the oxide spacer into a dehydrogenized oxide spacer having an electrically insulating region therein with a Si—OH/Si—O ratio of less than about 0.05 in the electrically insulating region.

2. The method of claim 1, wherein the plasma is generated from a reactant gas comprising nitrogen and/or oxygen.

3. The method of claim 2, wherein the reactant gas comprises at least one gas selected from a group consisting of N₂, O₂, O₃ and N₂O.

4. The method of claim 1, wherein said removing is followed by forming an electrically insulating spacer on a sidewall of the oxide spacer.

5. The method of claim 1, wherein the oxide spacer comprises a first oxide spacer and a second oxide spacer, and forming an oxide spacer further comprising:
conformally forming the first oxide spacer layer on the semiconductor substrate;
performing a first ion implantation process using as ion implantation masks the gate insulation film, the gate electrode and the first oxide spacer layer formed on the gate insulation film and sidewalls of the gate electrode;
conformally forming a second oxide spacer layer on the semiconductor substrate.

6. The method of claim 5, wherein the plasma treatment process is performed using a gas containing nitrogen (N) or oxygen (O) as a reactant gas.

7. The method of claim 6, wherein the reactant gas is selected from N₂, O₂, O₃, N₂O, and combinations thereof.

8. The method of claim 5, before performing the first ion implantation process, further comprising forming a first oxide spacer on both sidewalls of the gate insulation film and the gate electrode by etching the first oxide spacer layer, wherein the dehydrogenizing of the first and second oxide spacer layers comprises dehydrogenizing the first oxide spacer and the second oxide spacer layer.

9. The method of claim 5, after the dehydrogenizing of the first and second oxide spacer layers, further comprising:
conformally forming a third nitride spacer layer on the second oxide spacer layer;
forming first, second and third nitride spacers on sidewalls of the gate insulation film and the gate electrode by etching the first, second and third nitride spacer layers; and
performing a second ion implantation process using the first and second oxide spacers as ion implantation masks.

10. The method of claim 1, wherein the oxide spacer comprises a first oxide spacer and a second oxide spacer, and forming an oxide spacer further comprises:
conformally forming the first oxide spacer layer on the semiconductor substrate;
dehydrogenizing the first oxide spacer layer by performing a first plasma treatment process on the semiconductor substrate;
performing a first ion implantation process using as ion implantation masks the gate insulation film, the gate electrode and the first oxide spacer layer formed on the gate insulation film and sidewalls of the gate electrode; and
conformally forming the second oxide spacer layer on the semiconductor substrate.

11. The method of claim 10, wherein the first plasma treatment process is performed using a gas containing nitrogen (N) or oxygen (O) as a reactant gas.

12. The method of claim 11, wherein the reactant gas is selected from N₂, O₂, O₃, N₂O, and combinations thereof.

13. The method of claim 10, before performing the first ion implantation process, further comprising forming a first oxide spacer on both sidewalls of the gate insulation film and the gate electrode by etching the first oxide spacer layer.

14. The method of claim 13, after the forming of the second oxide spacer layer, further comprising:
dehydrogenizing the second oxide spacer layer by performing a second plasma treatment process on the semiconductor substrate;
conformally forming a third nitride spacer layer on the second oxide spacer layer;
forming second and third nitride spacers on both sidewalls of the first oxide spacer by etching the second and third nitride spacer layers; and
performing a second ion implantation process using the second and third nitride spacers as ion implantation masks.

15. The method of claim 14, wherein the first and second oxide spacer layers are low temperature oxide (LTO) layers.

16-20. (canceled)
